(19) United States
(12) Patent Application Publication
(10) Pub. No.: US 2018/0272390 A1
(43) Pub. Date: Sep. 27, 2018

(54) BATCH PROCESSING LOAD LOCK CHAMBER

(71) Applicant: Applied Materials, Inc., Santa Clara, CA (US)

(72) Inventor: Ernesto ULLOA, San Jose, CA (US)

(21) Appl. No.: 15/469,113

(22) Filed: Mar. 24, 2017

(51) Int. Cl. B08B 7/00; H01L 21/677; H01L 21/02; H01L 21/3065

(52) U.S. Cl. CPC B08B 7/0035; H01L 21/3065; H01L 21/02274; H01L 21/6773

(57) ABSTRACT

Embodiments of the disclosure generally relate to an improved batch processing load lock chamber, a cluster tool having the same and a method of using the improved load lock chamber to clean a plurality of substrates disposed within. In one embodiment, a load lock chamber includes a chamber body, a cassette disposed in the chamber body, a remote plasma source, a plurality of inlet nozzles and a plurality of outlet ports. The chamber body has a plurality of substrate transfer slots formed therein. The cassette has a plurality of substrate storage slots and is configured to move up and down within the chamber body. The plurality of inlet nozzles is coupled to the remote plasma source and faces a processing region defined within the chamber body. The plurality of outlet ports faces the plurality of inlet nozzles across the processing region.

### BACKGROUND

### Field

Embodiments of the disclosure generally relate to an improved batch processing load lock chamber, and a method for processing semiconductor substrates using the same.

### Description of the Related Art

A cluster tool allows for automatic transfer of a substrate between process chambers for use in different processes like chemical vapor deposition, physical vapor deposition, etching and the like. The cluster tool is used for parallel processing of multiple substrates to increase throughput and productivity. Typical configuration includes a conventional load lock chamber for loading substrates, a transfer chamber, and several process chambers which can perform the deposition and etching processes. In some applications, one or more of the processing chambers is replaced by a pre-clean chamber. The substrates are transferred between chambers under vacuum using a transfer mechanism to prevent exposure to air which prevents oxidation and contamination.

The load lock chamber is an auxiliary chamber in a cluster tool used to introduce substrates into the transfer chamber without exposing the vacuum condition inside the transfer chamber to the air outside the cluster tool. A vacuum pumping system connected to the load lock chamber pumps down the pressure inside the load lock chamber to a level compatible with the pressure inside the transfer chamber of the cluster tool. The load lock chamber may include a cassette for holding a plurality of substrates.

Prior to processing, the substrates are cleaned in a pre-clean chamber attached to the transfer chamber. During the pre-clean process, impurities such as native oxides, organic materials are removed from the substrates in order to prepare them for subsequent processing. The impurities affect the electrical properties of the substrates. For example, silicon oxide films formed by exposure of silicon substrates to oxygen, are electrically insulating and hence undesirable.

The presence of the pre-clean chamber reduces the number of processing chambers that can attach to the transfer chamber. Thus the flexibility to run different processes and the throughput is reduced.

### SUMMARY

Embodiments of the disclosure generally relate to an improved batch processing load lock chamber, a cluster tool having the same and a method of using the improved load lock chamber to clean a plurality of substrates disposed within. In one embodiment, a load lock chamber includes a chamber body, a cassette disposed in the chamber body, a remote plasma source, a plurality of inlet nozzles and a plurality of outlet ports. The chamber body has a plurality of substrate transfer slots formed therein. The cassette has a plurality of substrate storage slots and is configured to move up and down within the chamber body. The plurality of inlet nozzles is coupled to the remote plasma source and faces a processing region defined within the chamber body. The plurality of outlet ports faces the plurality of inlet nozzles across the processing region.

In another embodiment of the disclosure, a load lock chamber includes a chamber body, a cassette disposed in the chamber body, a remote plasma source, a plurality of inlet nozzles, a plurality of outlet ports, a pump coupled to the plurality of outlet ports, one or more heating elements disposed around the chamber body, one or more cooling channels disposed around the chamber body, an inlet manifold, an outlet manifold and a lift actuator configured to raise and lower the cassette. The chamber body has a plurality of substrate transfer slots formed therein. The cassette has a plurality of substrate storage slots. The plurality of inlet nozzles is coupled to the remote plasma source and faces a processing region defined within the chamber body. The plurality of outlet ports faces the plurality of inlet nozzles across the processing region. The inlet manifold connects the remote plasma source to the plurality of inlet nozzles. The outlet manifold connects the plurality of outlet ports to the pump.

In yet another embodiment of the disclosure, a method for processing a plurality of substrates disposed in a load lock chamber is provided. The method includes loading a cassette disposed in a chamber body with a plurality of substrates through a first substrate transfer slot formed through the chamber body, flowing radicals from a remote plasma source horizontally across the plurality of substrates disposed in the cassette and transferring the plurality of substrates after exposure to the radicals out of the chamber body through a second substrate transfer slot formed through the chamber body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a simplified front cross-sectional view of an improved batch processing load lock chamber.

FIG. 2 is a simplified top cross-sectional view of the load lock chamber.

FIG. 3 is a simplified front cross-sectional view of a cassette having a plurality of substrate transfer slots.

FIG. 4 is a simplified front cross-sectional view of the wall of the load lock chamber body.

FIG. 5 is a schematic view of a conventional cluster tool having a conventional load lock chamber.

FIG. 6 is a schematic view of a cluster tool having the improved batch processing load lock chamber.

FIG. 7 is a block diagram of a method for processing substrates disposed in the improved batch processing load lock chamber.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the disclosure generally relate to an improved batch processing load lock chamber, a cluster tool having the same and a method of using the improved load lock chamber to clean a plurality of substrates disposed within.

The improved batch processing load lock chamber described herein increases both the speed of processing and yield of substrates processed within a cluster tool. Incorporation of a pre-clean capability in the load lock chamber increases system efficiency, resulting in an increase in the number of substrates that can be processed by the cluster tool in a given time, leading to an increased throughput.

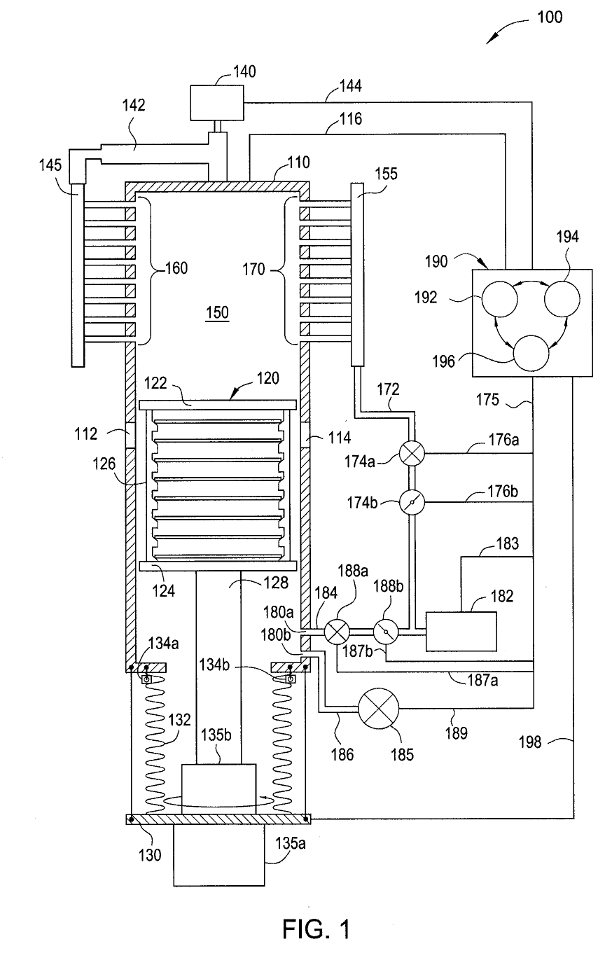

FIG. 1 is a simplified front cross-sectional view of an improved batch processing load lock chamber 100 according to one embodiment of the invention. The load lock chamber 100 has a chamber body 110 and a cassette 120 configured to move vertically up and down the chamber body 110. The chamber body 110 has at least one substrate transfer slot 112 for inserting substrates onto the cassette 120 and at least one substrate transfer slot 114 for removing the substrates from the cassette 120. In the embodiment shown in FIG. 1, the transfer slots 112 and 114 are selectively sealed by slit valve doors (not shown). The chamber body 110 encompasses a processing region 150. One or more inlet nozzles, collectively referenced as 160 and one or more outlet ports, collectively referenced as 170 are disposed on opposing sides of the processing region 150 within the chamber body 110. For example, in the embodiment shown in FIG. 1, the chamber body 110 contains eight inlet nozzles collectively referenced as 160 and eight outlet ports collectively referenced as 170 such that each outlet port corresponds to each inlet nozzle. In a different embodiment, the chamber body may contain up to twenty-five inlet nozzles and twenty-five outlet ports. Alternatively, the number of inlet nozzles 160 may also be different than the number of outlet ports 170. Each inlet nozzle 160 faces the processing region 150 and each outlet port 170 faces each inlet nozzle 160 across the processing region 150.

The cassette 120 is supported onto a platform 130 by a shaft 128. The shaft 128 is coupled to a lift actuator 135a, which is capable of raising or lowering the cassette 120 disposed within the chamber 100 as needed. In some embodiments, the lift actuator 135a may be a lift motor. In the embodiment shown in FIG. 1, an extension tube 132, such as but not limited to a bellows, is utilized to seal the platform 130 to the chamber body 110. The extension tube 132 is attached to the chamber body 110 by a fastening mechanism, such as but not limited to clamps 134a and 134b. The platform 130 supports a rotary actuator 135b that is coupled to the shaft 128. In some embodiments, the rotary actuator 135b may be a rotary motor. The rotary actuator 135b is operable to rotate the cassette 120.

The cassette 120 has a top surface 122, a bottom surface 124 and a wall 126. The wall 126 of the cassette 120 has a plurality of substrate storage slots collectively referenced as 250. Each substrate storage slot 250 is configured to hold a substrate 200 therein. Each substrate storage slot 250 is evenly spaced along the wall 126 of the cassette 120. For example, in the embodiment shown in FIG. 3, the cassette 120 shows each of the plurality of substrate storage slots collectively referenced as 250, respectively holding one of the plurality of substrates collectively referenced as 200. Similarly, in the embodiment shown in FIG. 1, the cassette 120 has eight substrate storage slots to hold eight substrates. In a different embodiment, the cassette 120 may include up to twenty-five substrate storage slots for holding up to twenty-five substrates.

The cassette 120 is operatively coupled to the lift actuator 135a and a rotary actuator 135b. The lift actuator 135a raises and lowers the cassette 120, thus moving the cassette 120 between a processing position in the processing region 150 and a transfer position that aligns each substrate storage slot 250 with the substrate transfer slots 112 and 114 formed on the chamber body 110. The rotary actuator 135b rotates the cassette 120, as the substrates 200 undergo processing in the processing position.

The inlet nozzles 160 on the chamber body 110 are connected to an inlet manifold 145. The inlet manifold 145 is connected to a remote plasma source 140 by an inlet pipe 142. The remote plasma source 140 is configured to generate gaseous radicals that flow through the inlet pipe 142 and the inlet nozzles 160 into the processing region 150 inside the chamber body 110. The inlet manifold 145 is configured for evenly distributing gaseous radicals through the inlet nozzles 160 into the processing region 150 of the chamber 100.

The remote plasma source 140 is operatively coupled to one or more gas sources, where the gas may be at least one of ammonia, hydrogen, nitrogen or an inert gas like argon or helium. The generation as well as the distribution of gaseous radicals activated in the remote plasma source 140 is controlled by a controller 190.

The outlet ports 170 of the chamber body 110 are connected to an outlet manifold 155. The outlet manifold 155 is connected to an on/off valve 174a in series with a throttle valve 174b by an outlet pipe 172 that is further connected to a pump 182, located downstream of the on/off valve 174a and the throttle valve 174b. The on/off valve 174a and the throttle valve 174b are configured to remove the gaseous radicals and byproducts from the processing region 150 through the outlet ports 170 utilizing the suction force of the pump 182. The operation of the on/off valve 174a and the throttle valve 174b is controlled by the controller 190 through the connecting wires 176a and 176b respectively.

The chamber body 110 includes an exhaust port 180a which is connected to the pump 182 by an exhaust pipe 184. The exhaust pipe 184 is connected to an on/off valve 188a in series with a throttle valve 188b and to the pump 182, located further downstream of the on/off valve 188a and the throttle valve 188b. The on/off valve 188a and the throttle valve 188b are configured to remove air from the processing region 150 through the exhaust port 180a utilizing the suction force of the pump 182, in order to pump down the processing region 150 to a vacuum. The operation of the on/off valve 188a and the throttle valve 188b is controlled by the controller 190 through the connecting wires 187a and 187b respectively.

The chamber body 110 further includes a vent port 180b which is connected to a vent valve 185 by a vent pipe 186. The vent valve 185 is configured to provide air into chamber 100. The operation of the vent valve 185 is controlled by the controller 190 through the connecting wire 189. The air pressure within the processing region 150 inside the chamber 100 is thus regulated by the pump 182 and the vent valve 186, which are controlled by the controller 190.

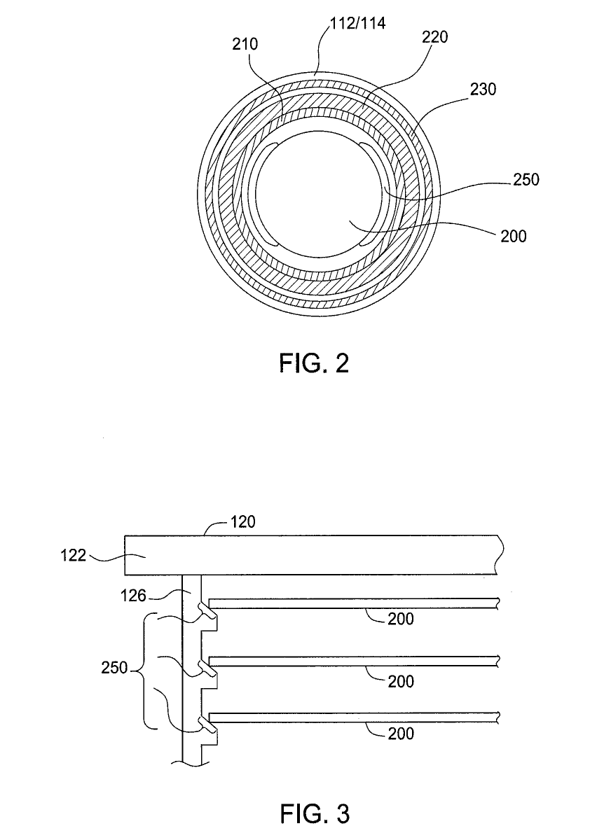

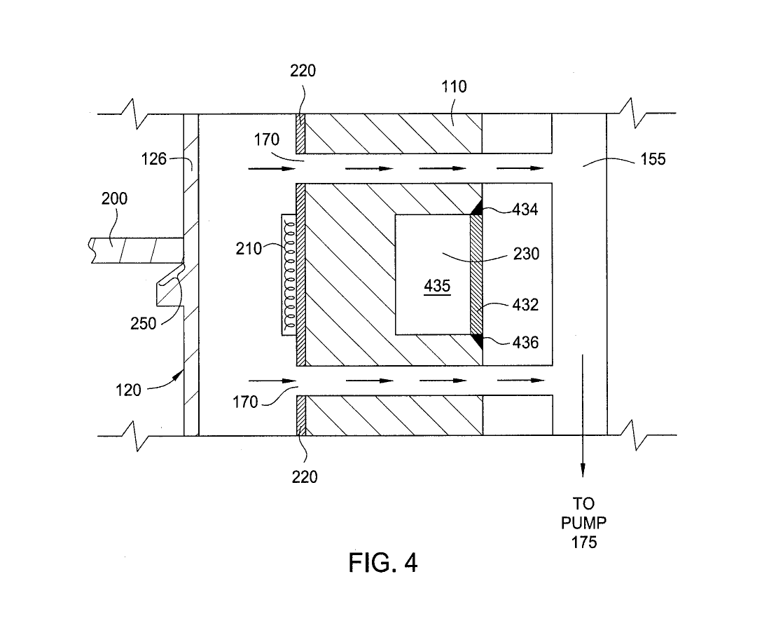

The chamber body 110 includes one or more heating elements 210 configured to heat the chamber 100. The heating element 210 is shown in both FIG. 2, which is a simplified top cross-sectional view of the chamber 100 and FIG. 4, which is a simplified front cross-sectional view of the wall of the chamber 100. The heating element 210 is disposed on a reflective surface 220 on the wall of the chamber body 110 facing the cassette 120. In the embodiments shown in FIGS. 2 and 4, the heating element 210 is disposed around the chamber body 110 and may be a resistive coil, a lamp, or a ceramic heater. The power to the heating element 210 is controlled by the controller 190 through feedback received from temperature sensors (not shown), monitoring the temperature of the chamber body 110. The reflective surface 220 is a coating or a layer formed on the surface of the chamber body 110 facing the cassette 120.

One or more cooling channels 230 are disposed around the chamber body 110, as shown in FIGS. 2 and 4. In the embodiment shown in FIG. 4, the cooling channel 230 is formed by a groove 435 in the wall of the chamber body 110 and welding a cover plate 432 at locations 434, 436 to the chamber body 110 to enclose the groove 435. In other embodiments, the cooling channel 230 may be a coiling cylindrical tube fastened either to the outside of the chamber 110 or disposed in the groove 435 formed in the chamber body 110. A cooling agent, such as but not limited to water, may be circulated within the cooling channel 230. The flow of the cooling agent within the cooling channel 230 is controlled by the controller 190 through feedback received from temperature and/or flow sensors (not shown).

The controller 190 controls the operation of the load lock chamber 100 as well as the remote plasma source 140. The controller 190 is communicatively connected to the lift actuator 135a and the rotary actuator 135b by a connector 198. The controller 190 is communicatively connected to the pump 182 by a connector 183. The controller 190 is communicatively connected to the remote plasma source 140 by a connector 144 and to the heating element 210 and the cooling channel 230 on the chamber body 110 by the connector 116. The controller 190 includes a central processing unit (CPU) 192, a memory 194, and a support circuit 196. The CPU 192 may be any form of general purpose computer processor that may be used in an industrial setting. The memory 194 may be random access memory, read only memory, floppy, or hard disk drive, or other form of digital storage. The support circuit 196 is conventionally coupled to the CPU 192 and may include cache, clock circuits, input/output systems, power supplies, and the like.

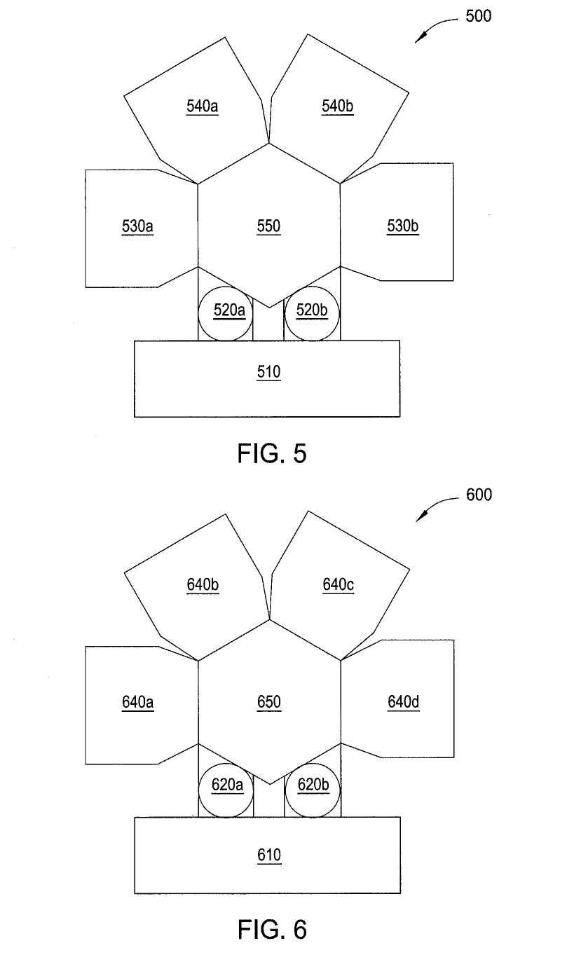

The load lock chamber 100 advantageously incorporates a pre-clean capability that is unavailable in conventional load lock chambers. This advantage is demonstrated clearly in FIGS. 5 and 6. FIG. 5 shows a schematic view of a conventional cluster tool 500 having a conventional load lock chamber, while FIG. 6 shows a schematic view of a cluster tool 600 having the improved load lock chamber 100. In FIG. 5, the cluster tool 500 includes a factory interface 510, two conventional load lock chambers 520a and 520b, two pre-clean chambers 530a and 530b, two processing chambers 540a and 540b and a transfer chamber 550. During manufacturing, substrates are first placed in the conventional load lock chambers 520a and 520b. The substrates are then removed from the load lock chambers 520a and 520b by a transfer mechanism (not shown) disposed in the transfer chamber 550 and placed into the pre-clean chambers 530a and 530b. After pre-cleaning, the substrates are moved by the transfer mechanism to the two processing chambers 540a and 540b for further processing. In contrast, as seen in FIG. 6, the cluster tool 600 includes two improved load lock chambers 620a and 620b with pre-clean capability as well as the factory interface 610, four processing chambers 640a, 640b, 640c and 640d and a transfer chamber 650. During manufacturing, substrates 200 are placed in the load lock chambers 620a and 620b, where the substrates are pre-cleaned after the load lock chambers 620a and 620b are pumped down to vacuum. Subsequently, the pre-cleaned substrates are removed by a transfer mechanism (not shown) and placed in the four processing chambers 640a, 640b, 640c and 640d for further processing. The lack of single purpose pre-clean chambers coupled to the transfer chamber 650 frees up space for two additional processing chambers to be coupled to the transfer chamber 650. Thus, the additional processing chambers of the cluster tool 600 compared to the cluster tool 500 enables the cluster tool 600 to enjoy faster throughput.

The improved load lock chamber 100 is utilized for pre-cleaning a plurality of substrates before the substrates undergo processing in processing chambers within the cluster tool 600. Initially, the cassette 120 is raised by the lift actuator 135a so that each of the empty substrate storage slots 250 on the cassette 120 sequentially aligns with the substrate transfer slot 112 on the chamber body 110 of the chamber 100. Substrates 200 are loaded into the substrate storage slots 250 one substrate at a time by incrementally raising or lowering the cassette 120, until all the substrate storage slots 250 are occupied by substrates 200 and the cassette 120 is full. The operation of the lift actuator 135a is precisely controlled by the controller 190 such that the substrates 200 are efficiently and correctly loaded onto the respective substrate storage slots 250. Once the cassette 120 is full or otherwise ready for pre-cleaning, the cassette 120 is raised into the processing region 150 such that the substrate storage slots 250 in the cassette 120 is aligned with the inlet nozzles 160 and the outlet ports 170. The positioning of the substrate storage slots 250 laterally between the inlet nozzles 160 and the outlet ports 170 ensures that gaseous radicals distributed from the inlet nozzles 160 uniformly contact the surface of the substrates 200 before they exit through the outlet ports 170.

Once the cassette 120 is loaded with the substrates 200, the controller 190 turns on the on/off valve 188a and the throttle valve 188b to vacuum down the processing region 150 using the pump 182. The controller 190 maintains the desired pressure within the processing region 150 by regulating the inflow and evacuation of air from the processing region 150 through the vent valve 185 and the pump 182 respectively, during and after the pre-cleaning process.

The remote plasma source 140 produces gaseous radicals by activating a gas supplied by a gas source (not shown) operatively coupled to the remote plasma source 140. In one embodiment, the gas supplied to the remote plasma source 140 may be at least one of ammonia, hydrogen, nitrogen or an inert gas like argon or helium. The gaseous radicals activated in the remote plasma source 140 then travel through the inlet pipe 142 to the inlet manifold 145, from where they are distributed in the processing region 150 via the inlet nozzles 160. The cassette 120 is rotated by the rotary actuator 135b as the substrates are exposed to the gaseous radicals. While gaseous radicals flow horizontally from the inlet nozzles 160 and across the plurality of substrates 200, the chamber body 110 is heated to a temperature of about 300-350 degrees Celsius. The application of heat to the chamber body 110 ensures that the gaseous radicals remain sufficiently energized as they flow over the substrates 200. The controller 190 maintains the temperature of the chamber body 110 at the desired level by controlling the heating elements 210 and the cooling channels 230 through feedback received from temperature sensors (not shown).

As the gaseous radicals flow across the substrates, the reaction between the gaseous radicals and impurities such as a native oxide or organic material present on the surface of the substrates 200 creates a gaseous byproduct that removes the impurity and leaves the substrates 200 cleaned. In one embodiment, the gaseous byproduct may be a salt of the native oxide layer. The unreacted gaseous radicals and any gaseous byproducts are removed by the pump 182. The unreacted gaseous radicals and gaseous byproducts exit the processing region 150 through the outlet ports 170 and the outlet manifold 155. The controller 190 turns on the on/off valve 174a and the throttle valve 174b to remove the unreacted gaseous radicals and gaseous byproducts through the pump 182 connected to the outlet manifold 155 via the on/off valve 174a and the throttle valve 174b.

The substrates 200 are thus cleaned prior to subsequent processing in the processing chambers 640. The clean substrates are transferred out of the chamber body 110 through a second substrate transfer slot 114 formed through the chamber body 110. Each of the substrate storage slots 250 of the cassette 120 is sequentially aligned with the substrate transfer slot 114 by the lift actuator 135a. The substrates 200 are unloaded from the substrate storage slots 250 one substrate at a time by incrementally raising or lowering the cassette 120, until all the substrate storage slots 250 in the cassette 120 are emptied. The substrates 200 are efficiently unloaded from the respective substrate storage slots 250 into the transfer chamber 650 by the transfer mechanism (not shown). The transfer mechanism then places the substrates 200 into the processing chambers 640 for further processing. In one embodiment, the transfer mechanism is a robot.

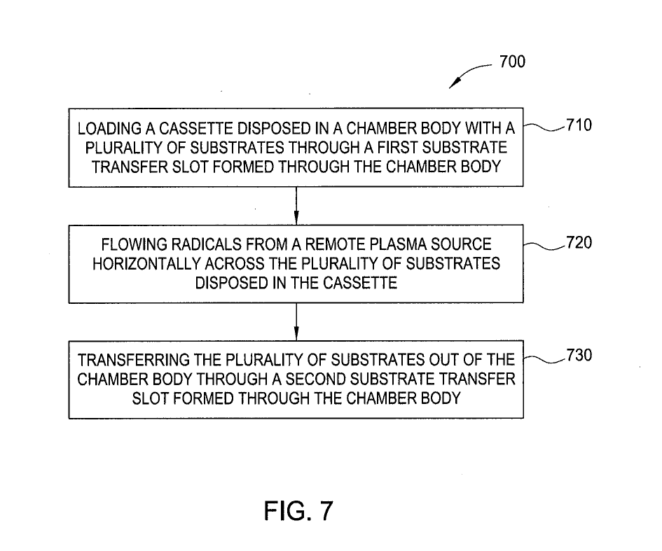

FIG. 7 is a block diagram of a method for processing substrates disposed in the improved batch processing load lock chamber, according to another embodiment of the present disclosure. The method 700 begins at block 710 by loading a cassette disposed in a chamber body with a plurality of substrates through a first substrate transfer slot formed through the chamber body. The cassette has a plurality of substrate storage slots for accommodating the plurality of substrates. Each substrate storage slot on the cassette is indexed to align with the first substrate transfer slot in order to load a substrate therein. The cassette is moved vertically by a lift actuator along the chamber body as all the substrates are loaded for subsequent processing inside the load lock chamber. Once the cassette is full or otherwise ready for pre-cleaning, the cassette is raised into the processing region within the chamber body such that the substrate storage slots in the cassette are aligned with the inlet nozzles and the outlet ports. After the substrate storage slots are positioned laterally between the inlet nozzles and the outlet ports the pressure inside the chamber body is reduced to a vacuum state. In one embodiment of the disclosure, air within the processing region of the chamber body is removed through a vacuum pump.

At block 720, gaseous radicals are flown across the plurality of substrates disposed in the chamber body. The cassette is simultaneously rotated to provide uniform exposure across the substrates to the radicals. The gaseous radicals are produced in a remote plasma source by activating at least one of ammonia, hydrogen, nitrogen or an inert gas like argon or helium. The gaseous radicals flow from the remote plasma source and through an inlet manifold connected to one or more inlet nozzles on the chamber body to enter the chamber. While the radicals are flown horizontally from the inlet nozzles and across the plurality of substrates, the chamber is heated to a temperature of about 300-350 degrees Celsius. The temperature of the chamber body is maintained at the desired level by controlling the heat generated by heating element and the heat removed by the cooling channel disposed around the chamber body.

The flow of gaseous radicals across the plurality of substrates disposed in the chamber helps remove impurities present on the substrates such as a native oxide or an organic material. The energized radicals react with the impurities to form a byproduct that is readily removable from the substrate. For example, silicon oxides formed on a silicon substrate may be removed by flowing fluoride radicals over the silicon substrate to form a thin layer of a salt containing silicon and fluorine, which subsequently dissociates into volatile gaseous byproducts. The gaseous radicals and gaseous byproducts are removed by a pump connected to the outlet ports formed in the chamber body via an outlet manifold. The pre-cleaning process of removing impurities prepares the substrates for further processes such deposition, etching, etc.

At block 730, the plurality of substrates, after pre-cleaning, are transferred out of chamber body through a second substrate transfer slot formed through the chamber body. Each substrate storage slot on the cassette is aligned with the second substrate transfer slot in order to remove the substrates. The substrates are transferred out of the cassette and placed in the processing chamber for processing. After processing, the processed substrates are returned to the cassette. Once the cassette is filled with processed substrates, the processing region is vented and the substrates are removed from the load lock chamber into the factory interface.

The improved batch processing load lock chamber and the method for cleaning a plurality of substrates disposed within the load lock chamber increases the efficiency of the cluster tool utilized for processing substrates. Incorporation of a pre-clean capability in a load lock chamber increases system efficiency, resulting in an increase in the number of substrates that can be processed by the cluster tool over a given time. The pre-clean capability in the load lock chamber frees up space for one or more processing chambers that can accommodate additional substrates for processing. The pre-clean capability is incorporated by flowing gaseous radicals from a remote plasma source horizontally across the plurality of substrates disposed in the rotating cassette, removing the impurities as gaseous byproducts and leaving behind clean substrates that are removed for subsequent processing within processing chambers. Thus, a cluster tool incorporating the improved batch processing load lock chamber having a pre-cleaning capability has an increased throughput as compared to conventional systems. Equally importantly, the number of substrates processed in a given time would increase due to the availability of additional processing chambers in the cluster tool with the improved batch processing load lock chamber.

While the foregoing is directed to particular embodiments of the present disclosure, it is to be understood that these embodiments are merely illustrative of the principles and applications of the present invention. It is therefore to be understood that numerous modifications may be made to the illustrative embodiments to arrive at other embodiments without departing from the spirit and scope of the present inventions, as defined by the appended claims.

What is claimed is:

1. A load lock chamber comprising:
a chamber body having a plurality of substrate transfer slots formed therein;
a cassette disposed in the chamber body and having a plurality of substrate storage slots, the cassette configured to move up and down within the chamber body;
a remote plasma source;
a plurality of inlet nozzles facing a processing region defined within the chamber body, the plurality of inlet nozzles coupled to the remote plasma source; and
a plurality of outlet ports facing the plurality of inlet nozzles across the processing region.

2. The load lock chamber of claim 1 further comprising:
a pump connected to an exhaust port formed through the chamber body; and
one or more throttle valves coupled to the plurality of outlet ports and the exhaust port, the one or more throttle valves operable to control a ratio of flow through the plurality of outlet ports relative to the exhaust port.

3. The load lock chamber of claim 1 further comprising:
one or more heating elements disposed around the chamber body.

4. The load lock chamber of claim 3, wherein the one or more heating elements are a resistive coil, a ceramic heater or a lamp.

5. The load lock chamber of claim 1, wherein the chamber body further comprises:
one or more cooling channels.

6. The load lock chamber of claim 1, wherein an interior surface of the chamber body is reflective.

7. The load lock chamber of claim 1 further comprising:
a rotary actuator coupled to the cassette.

8. The load lock chamber of claim 1 further comprising:
an inlet manifold connecting the remote plasma source to the plurality of inlet nozzles.

9. The load lock chamber of claim 1 further comprising:
an outlet manifold coupled to the plurality of outlet ports.

10. The load lock chamber of claim 1 further comprising:
a lift actuator configured to raise and lower the cassette.

11. A load lock chamber comprising:
a chamber body having a plurality of substrate transfer slots formed therein;
a cassette disposed in the chamber body and having a plurality of substrate storage slots;
a remote plasma source;
a plurality of inlet nozzles facing a processing region defined within the chamber body, the plurality of inlet nozzles coupled to the remote plasma source;
a plurality of outlet ports facing the plurality of inlet nozzles across the processing region;
one or more heating elements disposed around the chamber body;
one or more cooling channels disposed around the chamber body;
an inlet manifold connecting the remote plasma source to the plurality of inlet nozzles;
an outlet manifold coupled to the plurality of outlet ports; and
a lift actuator configured to raise and lower the cassette.

12. The load lock chamber of claim 11, wherein the one or more heating elements are a resistive coil, a ceramic heater or a lamp.

13. The load lock chamber of claim 11 further comprising:
a pump connected to an exhaust port formed through the chamber body; and
one or more throttle valves coupled to the plurality of outlet ports and the exhaust port, the one or more throttle valves operable to control a ratio of flow through the plurality of outlet ports relative to the exhaust port.

14. The load lock chamber of claim 11 further comprising:
a rotary actuator coupled to the cassette.

15. A method for processing a plurality of substrates disposed in a load lock chamber, comprising:
loading a cassette disposed in a chamber body with a plurality of substrates through a first substrate transfer slot formed through the chamber body;
flowing radicals from a remote plasma source horizontally across the plurality of substrates disposed in the cassette; and
transferring the plurality of substrates out of the chamber body through a second substrate transfer slot formed through the chamber body.

16. The method of claim 15 further comprising:
heating the chamber body while flowing the radicals horizontally across the plurality of substrates.

17. The method of claim 16, wherein the chamber body is heated to a temperature between about 300 to about 350 degrees Celsius.

18. The method of claim 15 further comprising:
producing the radicals in the remote plasma source by activating at least one of ammonia, hydrogen, nitrogen and an inert gas.

19. The method of claim 15 further comprising:
removing a layer of impurity from the plurality of substrates.

20. The method of claim 19, wherein the layer of impurity comprises a native oxide or an organic material.
